(19) United States
(12) Patent Application Publication
(10) Pub. No.: US 2026/0237962 A1
(43) Pub. Date: Aug. 13, 2026

(54) LIGHT EMITTING DEVICE

(71) Applicant: FUJIFILM Business Innovation Corp., Tokyo (JP)

(72) Inventor: Daisuke Iguchi, Kanagawa (JP)

(73) Assignee: FUJIFILM Business Innovation Corp., Tokyo (JP)

(21) Appl. No.: 19/271,728

(22) Filed: Jul. 16, 2025

(30) Foreign Application Priority Data
Feb. 12, 2025 (JP) 2025-021094

(51) Int. Cl. H01S 5/02315; H01S 5/024; H01S 5/42; H05K 1/02; H05K 1/18

(52) U.S. Cl. CPC H01S 5/02315; H01S 5/02469; H01S 5/423; H05K 1/0207; H05K 1/0298; H05K 1/181

(57) ABSTRACT

A light emitting device includes: a light source board that includes a light emitting element including an anode and a cathode; a circuit board including a plurality of anode via conductors that conduct from a surface of the circuit board corresponding to a first direction up to a surface of the circuit board corresponding to a second direction opposite to the first direction, are connected to the anode, and are arranged in rows to form anode rows, and a plurality of cathode via conductors that conduct from the surface corresponding to the first direction up to the surface corresponding to the second direction, are connected to the cathode, are provided in the same number as the number of the anode via conductors, and are arranged in rows to form cathode rows, the circuit board holding the light source board on the surface corresponding to the first direction; and a drive unit that is connected to any one of the anode or the cathode and drives the light source board by switching between an ON state and an OFF state of current for causing the light emitting element to emit light, in which the anode rows of the plurality of anode via conductors included in the circuit board and the cathode rows of the plurality of cathode via conductors included in the circuit board are disposed to face each other.

### CROSS-REFERENCE TO RELATED APPLICATIONS

This application is based on and claims priority under 35 USC 119 from Japanese Patent Application No. 2025-021094 filed Feb. 12, 2025.

### BACKGROUND

### (i) Technical Field

The present disclosure relates to a light emitting device.

### (ii) Related Art

JP2021-150628A discloses a light emitting device in which a pair of capacitors is disposed on two sides of a light source with a light source interposed therebetween, and the inductance of a path through which current for light emission flows is reduced as compared to a case where a drive unit is not disposed on another side of the light source.

WO2021/033439A discloses a semiconductor laser drive device in which wiring inductance between a semiconductor laser and a laser driver is reduced.

JP2022-022184A discloses a light source driving system that is configured to include a current loop having low inductance and to achieve a fast turn-on time for a light source.

### SUMMARY

Aspects of non-limiting embodiments of the present disclosure relate to a light emitting device in which an increase in the inductance of a path through which current for causing a light emitting element to emit light flows can be suppressed in a case where a light source board including the light emitting element is disposed on one surface of a circuit board and an anode path and a cathode path for supplying current extend up to the other surface of the circuit board.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light emitting device including: a light source board that includes a light emitting element including an anode and a cathode; a circuit board including a plurality of anode via conductors that conduct from a surface of the circuit board corresponding to a first direction up to a surface of the circuit board corresponding to a second direction opposite to the first direction, are connected to the anode, and are arranged in rows to form anode rows, and a plurality of cathode via conductors that conduct from the surface corresponding to the first direction up to the surface corresponding to the second direction, are connected to the cathode, are provided in the same number as the number of the anode via conductors, and are arranged in rows to form cathode rows, the circuit board holding the light source board on the surface corresponding to the first direction; and a drive unit that is connected to any one of the anode or the cathode and drives the light source board by switching between an ON state and an OFF state of current for causing the light emitting element to emit light, in which the anode rows of the plurality of anode via conductors included in the circuit board and the cathode rows of the plurality of cathode via conductors included in the circuit board are disposed to face each other.

### BRIEF DESCRIPTION OF THE DRAWINGS

Exemplary embodiment(s) of the present invention will be described in detail based on the following figures, wherein:

FIG. 1 is a diagram showing a measurement apparatus of an exemplary embodiment of the present disclosure;

FIG. 2 is a schematic configuration diagram of a light emitting device;

FIG. 3 is a top view of a light source board;

FIG. 4 is a bottom view of the light source board;

FIG. 5 is a top view of a heat dissipation substrate;

FIG. 6 is a bottom view of the heat dissipation substrate;

FIG. 7 is a perspective view of via conductors;

FIG. 8 is a plan view of a first layer of a circuit board;

FIG. 9 is a plan view of a second layer of the circuit board;

FIG. 10 is a plan view of a fifth layer of the circuit board;

FIG. 11 is a plan view of a sixth layer of the circuit board;

FIG. 12 is a diagram showing an example of an equivalent circuit in a case where the light source board is driven by low-side driving; and

FIG. 13 is a diagram showing an aspect in which drive units are disposed in the light emitting devices.

### DETAILED DESCRIPTION

Hereinafter, an exemplary embodiment for embodying the technique of the present disclosure will be described in detail with reference to the drawings.

A measurement apparatus 1 of the present exemplary embodiment measures a distance between the measurement apparatus 1 and an object to be measured based on a time-of-flight (TOF) method. The TOF method is a method of measuring a distance between a measurement apparatus and an object to be measured by measuring a flight time of light from the measurement apparatus 1 to the object to be measured.

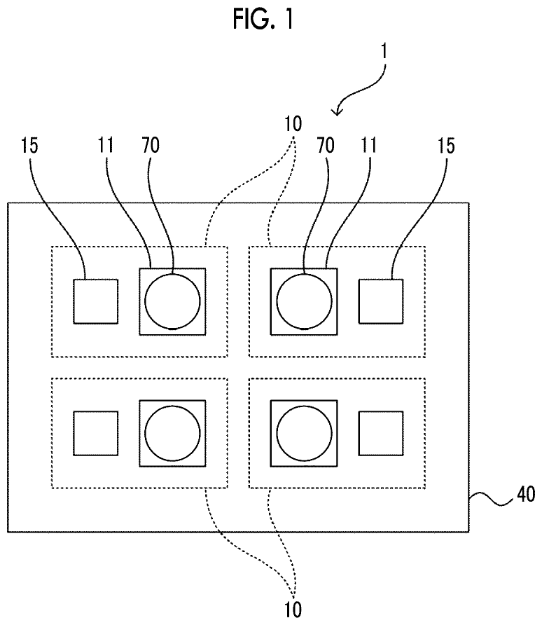

As shown in FIG. 1, the measurement apparatus 1 includes four measurement sections 10. The four measurement sections 10 are formed on one circuit board 40. The measurement section 10 includes a light emitting device 11 including a shaping optical system 70, and a light receiving device 15.

Specifically, each measurement section 10 of the measurement apparatus 1 measures a time from a timing at which light is emitted from the light emitting device 11 to a timing at which the emitted light is reflected by the object to be measured and received by the light receiving device 15.

Therefore, it is required that a rise time of light emission of the light emitting device 11 is short. As the rise time of the light emission is shorter, the accuracy of the measurement is higher. The rise time of the light emission of a light source is shorter as the inductance of a current path for supplying current for the light emission to the light source is smaller. That is, since current having a higher frequency is less likely to flow as the inductance of the current path is larger, a rise time of current for light emission of the light source is increased.

The rise time of the light emission is a rise time of current flowing for light emission, and is, for example, a time from a timing at which the current for light emission starts to rise to a time at which the light emission reaches 90% of the maximum amount of light.

### Configuration of Light Emitting Device 11

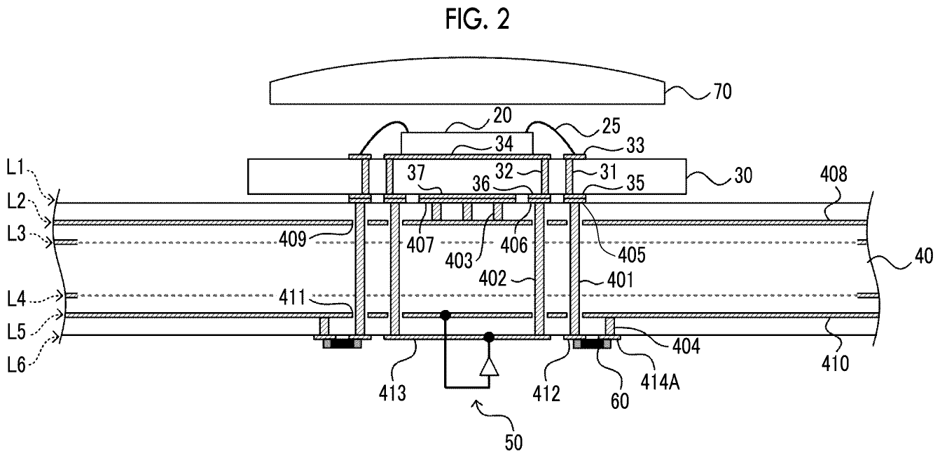

As shown in FIG. 2, the light emitting device 11 includes a light source board 20, a heat dissipation substrate 30, a circuit board 40, a drive unit 50, capacitors 60, and a shaping optical system 70.

In the following description, a surface corresponding to a first direction in the technique of the present disclosure will be described as an upper surface (an upper surface in FIG. 2), and a surface corresponding to a second direction in the technique of the present disclosure will be described as a lower surface (a lower surface in FIG. 2).

The light source board 20 is formed of a surface emitting laser element array in which a plurality of surface emitting laser elements are two-dimensionally arranged. The surface emitting laser element is, for example, a vertical resonator surface emitting laser element. Hereinafter, the vertical resonator surface emitting laser element will be referred to as a vertical cavity surface emitting laser (VCSEL). The VCSEL is an example of a light emitting element in the technique of the present disclosure.

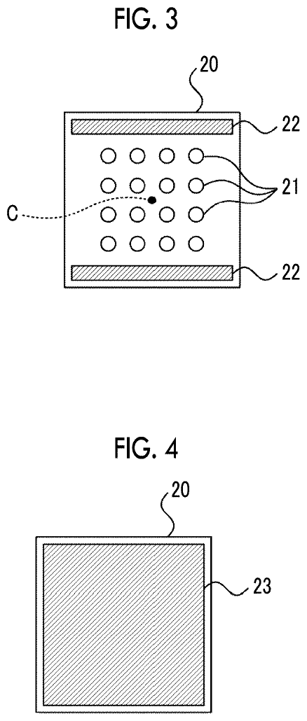

As shown in FIG. 3, an upper surface of the light source board 20 is provided with a plurality of VCSELs 21 two-dimensionally arranged and two anode wires 22 connected to anodes of the plurality of VCSELs 21. The two anode wires 22 are disposed on both sides of a central position C of the light source board 20 in a plan view. The anodes of the plurality of VCSELs 21 close to the central position C are commonly connected to each of the anode wires 22.

Further, as shown in FIG. 4, a lower surface of the light source board 20 is provided with a cathode wire 23 that is commonly connected to cathodes of the plurality of VCSELs 21. That is, the plurality of VCSELs 21 are connected in parallel. Since the plurality of VCSELs 21 are connected in parallel and driven, light having a high intensity is emitted as compared to a case where each of the plurality of VCSELs 21 is individually driven.

The heat dissipation substrate 30 holds the light source board 20 on an upper surface thereof and is connected to the circuit board 40 on a lower surface thereof. The heat dissipation substrate 30 is an insulating substrate of which the thermal conductivity is higher than the thermal conductivity of the circuit board 40. As the light intensity of the light source board 20 is increased, the amount of heat generated from the light source board 20 is also increased. Therefore, in order to efficiently dissipate heat generated from the light source board 20, for example, the light source board 20 may be mounted on the heat dissipation substrate 30.

FR-4, which is an example of a substrate of a glass epoxy resin used in a circuit board 40 to be described later, has a thickness of about 100 μm and a thermal conductivity of about 0.4 W/m·K. The thermal conductivity of copper (Cu) is about 360 W/m·K. The thermal conductivity shown here is a value at 25° C. unless otherwise specified.

For example, the heat dissipation substrate 30 is preferably a material having a thermal conductivity of 10 W/m·K or more and is more preferably a material having a thermal conductivity of 50 W/m·K or more. Further, for example, the heat dissipation substrate 30 is still more preferably a material having a thermal conductivity of 100 W/m·K or more.

Examples of the material having a thermal conductivity of 10 W/m·K or more include alumina (Al₂O₃) having a thermal conductivity of 20 to 30 W/m·K. Further, examples of the material having a thermal conductivity of 50 W/m·K or more include silicon nitride (Si₃N₄) having a thermal conductivity of about 85 W/m·K. Furthermore, examples of the material having a thermal conductivity of 100 W/m·K or more include aluminum nitride (AlN) having a thermal conductivity of 150 to 250 W/m·K. These may be referred to as ceramic materials. That is, the entire heat dissipation substrate 30 may be formed of, for example, a ceramic material. In addition, the heat dissipation substrate 30 may be another insulating material having a high thermal conductivity, such as silicon (Si) not doped with impurities. In the present exemplary embodiment, the heat dissipation substrate 30 is, for example, aluminum nitride (AlN).

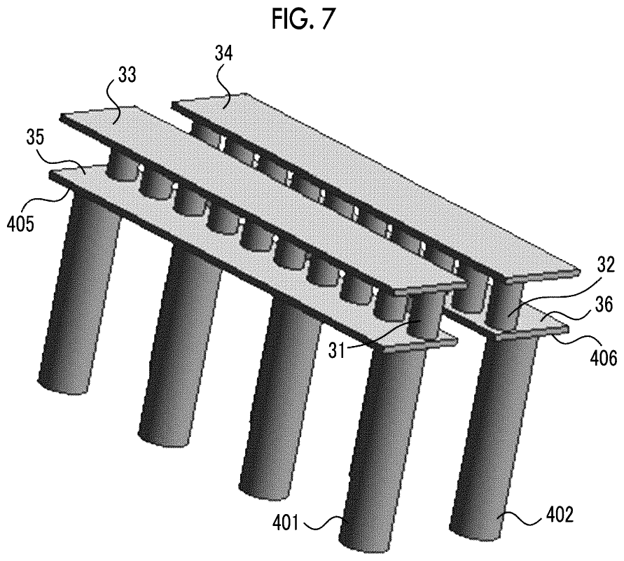

As shown in FIGS. 2 and 7, the heat dissipation substrate 30 includes a plurality of anode via conductors 31 and a plurality of cathode via conductors 32. FIG. 7 is a perspective view showing a state in which the plurality of anode via conductors 31, the plurality of cathode via conductors 32, a plurality of anode via conductors 401, and a plurality of cathode via conductors 402 are arranged on one side of both sides of the central position C of the light source board 20. In FIG. 7, a cathode wire 34 shows an arrangement position and does not show an accurate shape.

The plurality of anode via conductors 31 are via conductors that conduct from the upper surface of the heat dissipation substrate 30 up to the lower surface of the heat dissipation substrate 30, and are arranged in rows to form two anode rows. The plurality of anode via conductors 31 are connected to the anode wires 22 for the VCSELs 21.

The plurality of cathode via conductors 32 are via conductors that conduct from the upper surface of the heat dissipation substrate 30 up to the lower surface of the heat dissipation substrate 30 and are arranged in rows to form two cathode rows. The plurality of cathode via conductors 32 are provided in the same number as the number of the anode via conductors 31. The plurality of cathode via conductors 32 are connected to the cathode wire 23 for the VCSELs 21.

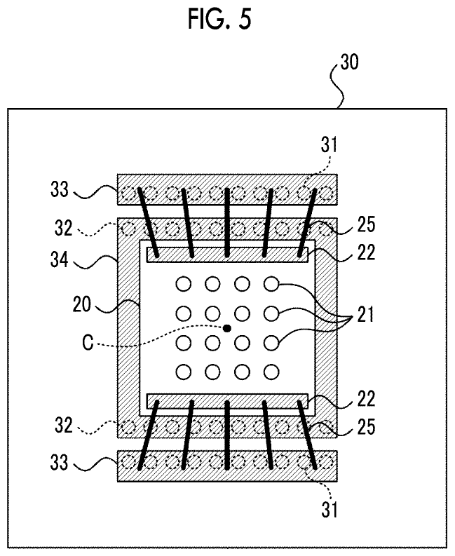

As shown in FIG. 5, the upper surface of the heat dissipation substrate 30 is provided with two anode wires 33 to be connected to the two anode wires 22 of the light source board 20, respectively, and a cathode wire 34 to be connected to the cathode wire 23 of the light source board 20. The two anode wires 33 are disposed on both sides of the central position C of the light source board 20 in a plan view. The two anode wires 22 and the two anode wires 33 are connected to each other by bonding wires 25.

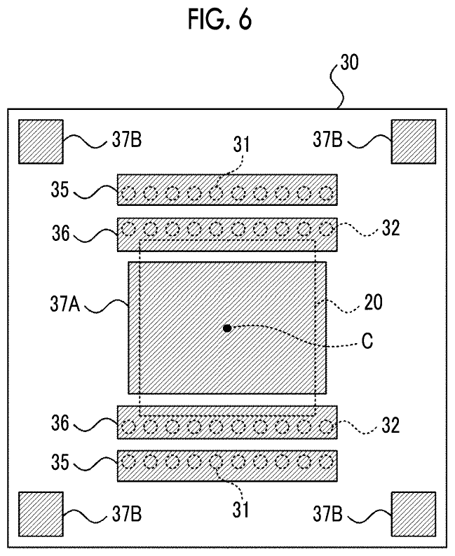

Further, as shown in FIG. 6, the lower surface of the heat dissipation substrate 30 is provided with two anode wires 35, two cathode wires 36, a ground wire 37A for heat dissipation provided at a central portion, and four ground wires 37B for heat dissipation provided at corners. The two anode wires 35 are disposed on both sides of the central position C of the light source board 20 in a plan view. The two cathode wires 36 are disposed on both sides of the central position C of the light source board 20 in a plan view.

As shown in FIG. 7, the anode wire 33 provided on the upper surface of the heat dissipation substrate 30 and the anode wire 35 provided on the lower surface of the heat dissipation substrate 30 are connected to each other by the plurality of anode via conductors 31 forming one anode row for each set of the anode wire 33 and the anode wire 35.

Furthermore, the cathode wire 34 provided on the upper surface of the heat dissipation substrate 30 and the cathode wire 36 provided on the lower surface of the heat dissipation substrate 30 are connected to each other by the plurality of cathode via conductors 32 forming one cathode row for each set of the cathode wire 34 and the cathode wire 36.

The anode rows of the plurality of anode via conductors 31 included in the heat dissipation substrate 30 and the cathode rows of the plurality of cathode via conductors 32 included in the heat dissipation substrate 30 are disposed to face each other.

The circuit board 40 is made of a substrate of a glass epoxy resin of which the thermal conductivity is lower than the thermal conductivity of the heat dissipation substrate 30. In the present exemplary embodiment, for example, FR-4, which is a glass epoxy resin, is used as a substrate of the circuit board 40.

The circuit board 40 is, for example, a six-layer board composed of a first layer L1 which is a wiring layer, a second layer L2 which is a ground layer for heat dissipation, a third layer L3 which is a wiring layer, a fourth layer L4 which is a wiring layer, a fifth layer L5 which is a ground layer for a current path, and a sixth layer L6 which is a wiring layer, in order from an upper surface side.

As shown in FIGS. 2 and 7, the circuit board 40 includes a plurality of anode via conductors 401, a plurality of cathode via conductors 402, a plurality of via conductors 403A and 403B for heat dissipation, and a plurality of via conductors 404A and 404B for ground connection.

The plurality of anode via conductors 401 are via conductors that conduct from the first layer L1 which is an upper surface of the circuit board 40 up to the sixth layer L6 which is a lower surface of the circuit board 40, and are arranged in rows to form two anode rows. The plurality of anode via conductors 401 are connected to the anode wires 22 for the VCSELs 21 via the heat dissipation substrate 30.

The plurality of cathode via conductors 402 are via conductors that conduct from the first layer L1 which is the upper surface of the circuit board 40 up to the sixth layer L6 which is the lower surface of the circuit board 40, and are arranged in rows to form two cathode rows. The plurality of cathode via conductors 402 are provided in the same number as the number of the anode via conductors 401. The plurality of cathode via conductors 402 are connected to the cathode wire 23 for the VCSELs 21 via the heat dissipation substrate 30.

The plurality of via conductors 403A and 403B for heat dissipation are via conductors that conduct from the first layer L1 which is the upper surface of the circuit board 40 up to the second layer L2 which is a ground layer for heat dissipation, and conduct the heat of the heat dissipation substrate 30 to the second layer L2 which is a ground layer for heat dissipation.

The plurality of via conductors 404A and 404B for ground connection are via conductors that conduct from the fifth layer L5 which is a ground layer for a current path up to the sixth layer L6 which is the lower surface of the circuit board 40.

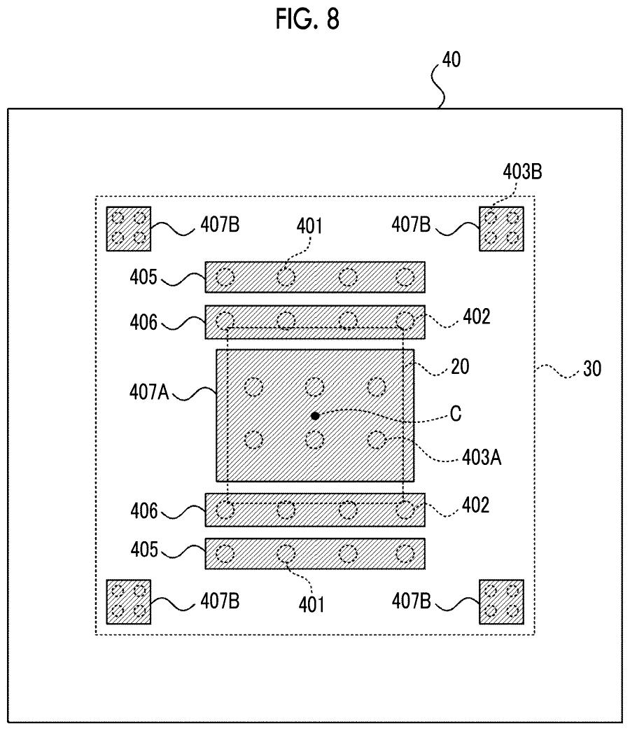

As shown in FIG. 8, the first layer L1, which is a wiring layer provided on the upper surface of the circuit board 40, is provided with two anode wires 405 that are connected to the two anode wires 35 of the heat dissipation substrate 30, respectively, two cathode wires 406 that are connected to the two cathode wires 36 of the heat dissipation substrate 30, respectively, a ground wire 407A for heat dissipation that is connected to the ground wire 37A for heat dissipation of the heat dissipation substrate 30, and four ground wires 407B for heat dissipation that are connected to the four ground wires 37B for heat dissipation of the heat dissipation substrate 30, respectively.

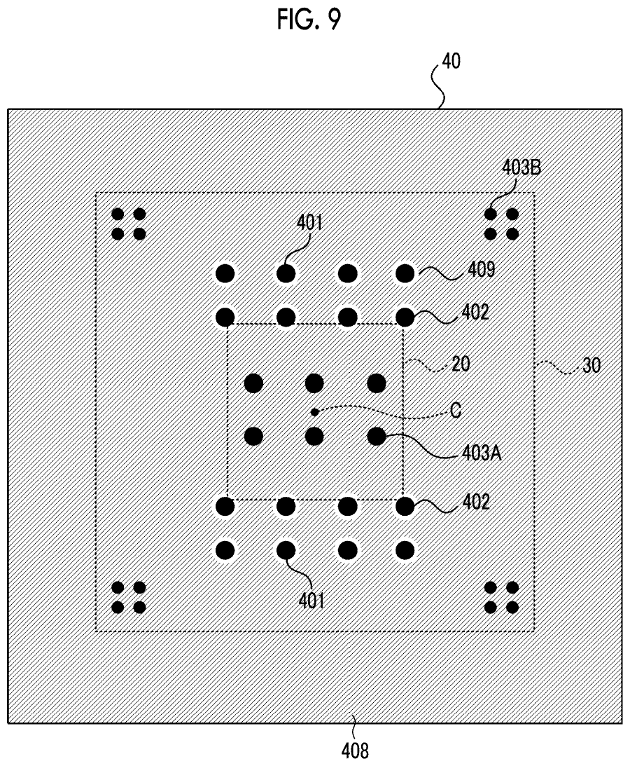

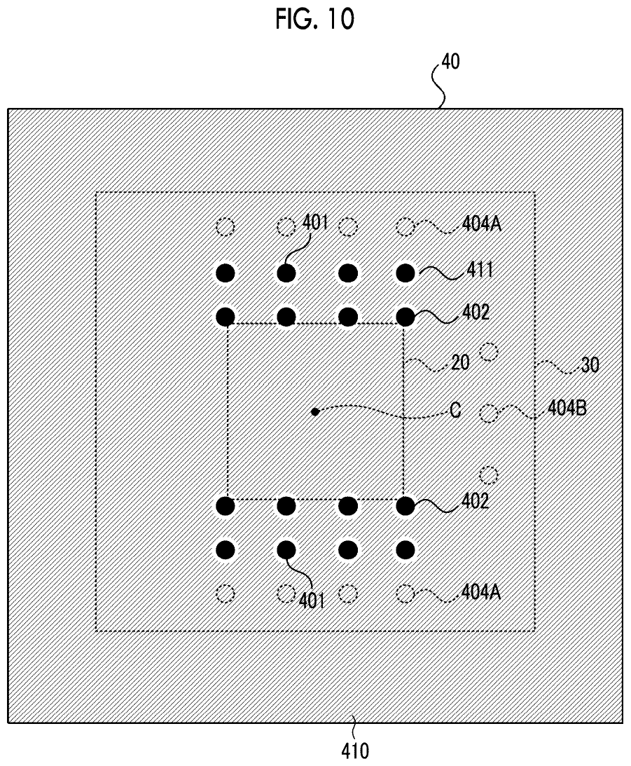

As shown in FIG. 9, the second layer L2, which is a ground layer for heat dissipation, is provided with a ground wire 408 for heat dissipation.

The ground wire 408 for heat dissipation includes a through-portion 409 that is individually provided for each of the plurality of anode via conductors 401 and the plurality of cathode via conductors 402. Each of the plurality of anode via conductors 401 and the plurality of cathode via conductors 402 penetrate the through-portions 409 individually provided in the second layer L2 which is a ground layer for heat dissipation.

Further, the ground wire 407A for heat dissipation is connected to the ground wire 408 for heat dissipation via the via conductors 403A for heat dissipation. Furthermore, the four ground wires 407B for heat dissipation are connected to the ground wire 408 for heat dissipation via the via conductors 403B for heat dissipation.

That is, the second layer L2, which is a ground layer for heat dissipation, is connected to the lower surface of the light source board 20 via the via conductors 403A and 403B for heat dissipation and the heat dissipation substrate 30 so that heat generated in the light source board 20 is conducted.

The ground wire 408 for heat dissipation of the ground layer for heat dissipation is not connected to a ground wire 410 for a current path of a ground layer for a current path, which will be described later, in a region overlapping with the light source board 20 in a plan view.

As shown in FIG. 10, the fifth layer L5, which is a ground layer for a current path, is provided with a ground wire 410 for a current path.

The ground wire 410 for a current path includes a through-portion 411 that is individually provided for each of the plurality of anode via conductors 401 and the plurality of cathode via conductors 402. Each of the plurality of anode via conductors 401 and the plurality of cathode via conductors 402 penetrate the through-portions 411 individually provided in the fifth layer L5 which is a ground layer for a current path.

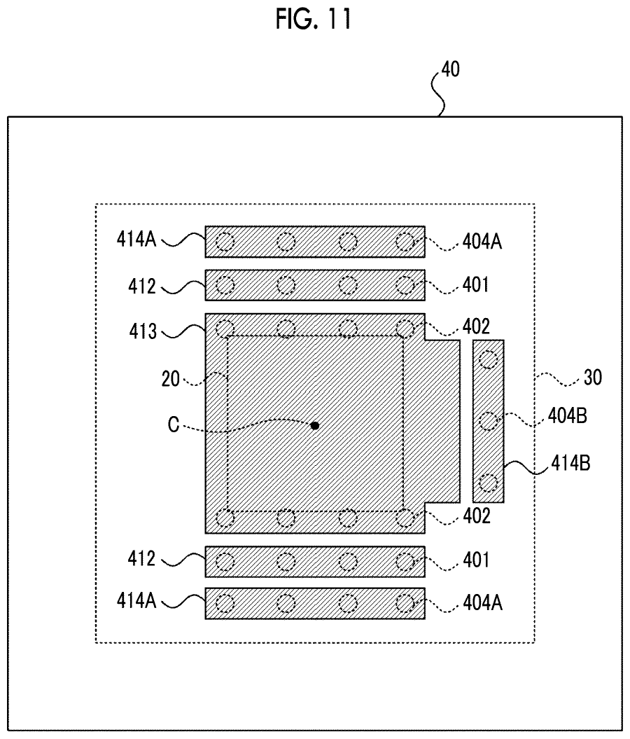

As shown in FIG. 11, the sixth layer L6, which is a wiring layer provided on the lower surface of the circuit board 40, is provided with two anode wires 412 that are connected to the two anode wires 405, respectively, a cathode wire 413 that is connected to the two cathode wires 406, two ground wires 414A that are connected to the ground wire 410 for a current path, and a ground wire 414B that is connected to the ground wire 410 for a current path.

The two ground wires 414A and the ground wire 410 for a current path are connected to each other by the via conductors 404A for ground connection. The ground wire 414B and the ground wire 410 for a current path are connected to each other by the via conductors 404B for ground connection. Further, the ground wire 414B is a wire to be connected to the drive unit 50, and is disposed between extension lines of the two cathode rows disposed on both sides of the central position C of the light source board 20 in a plan view from a lower surface side.

The two anode wires 412 and the two ground wires 414A are connected to each other by the respective capacitors 60.

The anode wire 405 provided on the upper surface of the circuit board 40 and the anode wire 412 provided on the lower surface of the circuit board 40 are connected to each other by the plurality of anode via conductors 401 that form one anode row for each set of the anode wires 405 and the anode wires 412.

Further, the cathode wire 406 provided on the upper surface of the circuit board 40 and the cathode wire 413 provided on the lower surface of the circuit board 40 are connected to each other by the plurality of cathode via conductors 402 that form one cathode row for each set of the cathode wire 406 and the cathode wire 413.

The anode rows of the plurality of anode via conductors 401 included in the circuit board 40 and the cathode rows of the plurality of cathode via conductors 402 included in the circuit board 40 are disposed to face each other.

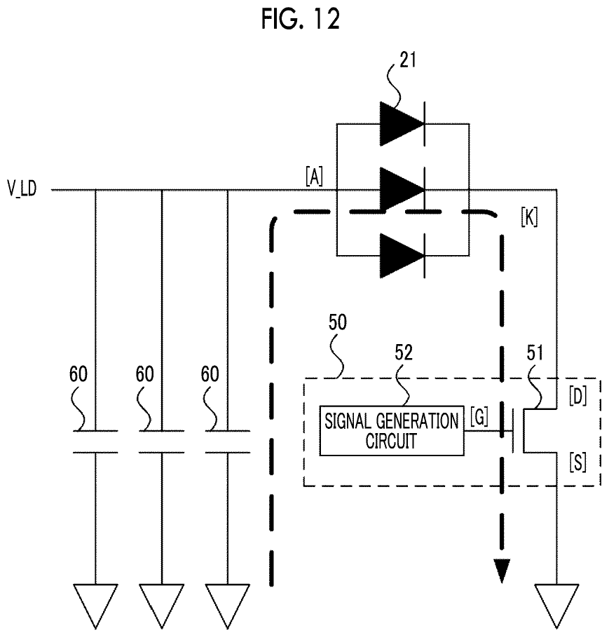

The drive unit 50 is connected to the cathode wire 23 of the light source board 20 and drives the light source board 20 by switching between an ON state and an OFF state of current which causes the plurality of VCSELs 21 to emit light. As shown in FIG. 12, the drive unit 50 includes an n-channel MOS transistor 51 and a signal generation circuit 52 that turns the MOS transistor 51 on and off. The drive unit 50 is held on the lower surface of the circuit board 40.

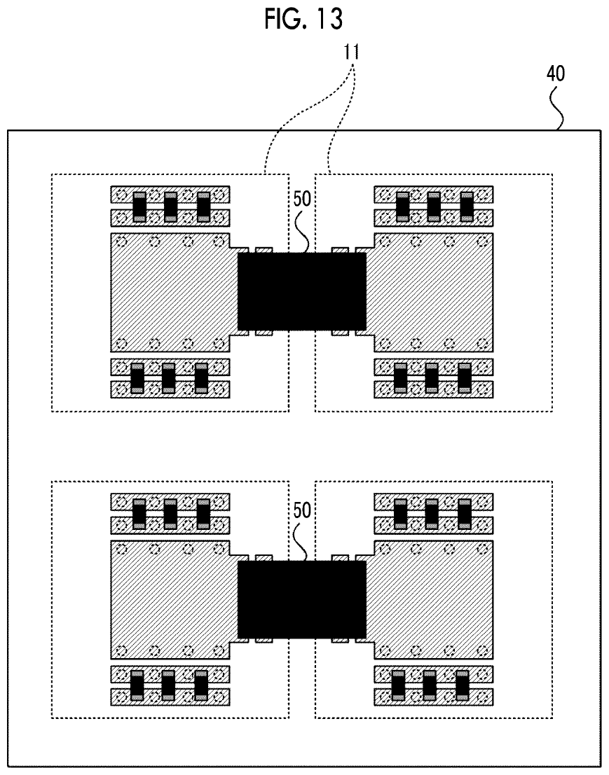

The drive unit 50 may be formed of an integrated circuit (IC) chip in which a plurality of n-channel MOS transistors 51 and a signal generation circuit 52 are packaged, and one set of right and left light emitting devices 11 may be driven by one drive unit 50, for example, as shown in FIG. 13.

The capacitors 60 are connected to the anode wires 22 of the light source board 20 and supply current that causes the plurality of VCSELs 21 to emit light. The capacitors 60 are held on the lower surface of the circuit board 40.

The number of capacitors 60 is not limited, and may be appropriately set according to specifications. Further, the type of the capacitor 60 to be used is also not limited, and the capacitor 60 may be a low ESL capacitor of which the equivalent series inductance (ESL) is reduced, a non-low ESL capacitor of which the equivalent series inductance (ESL) is larger than the equivalent series inductance of the low ESL capacitor, or a combination of both.

The shaping optical system 70 is provided above the light source board 20 to cover the light source board 20. The shaping optical system 70 is an optical system that irradiates a desired irradiation region with light emitted from the light source board 20, and is formed of, for example, a lens.

### Driving of Light Source Board 20

FIG. 12 is a diagram showing an example of an equivalent circuit in a case where the light source board 20 is driven by low-side driving. FIG. 12 shows the VCSELs 21 of the light source board 20, the drive unit 50, and the capacitors 60.

In a case where it is desired to drive the light source board 20 at a higher speed, it is preferable to drive the light source board 20 by low-side driving, for example. The low-side driving refers to a configuration in which a drive element such as a MOS transistor is positioned on a downstream side of a path (hereinafter, referred to as a current path) through which current flows to an object to be driven such as a VCSEL. Conversely, a configuration in which a drive element is positioned on an upstream side is referred to as high-side driving.

The light source board 20 is configured such that the plurality of VCSELs 21 are connected in parallel as described above. The anodes of the VCSELs 21 (denoted by [A] in FIG. 12) are connected to a power supply line.

The drive unit 50 includes the n-channel MOS transistor 51 and the signal generation circuit 52 that turns the MOS transistor 51 on and off. A drain (denoted by [D] in FIG. 12) of the MOS transistor 51 is connected to the cathodes (denoted by [K] in FIG. 12) of the VCSELs 21. A source (denoted by [S] in FIG. 12) of the MOS transistor 51 is connected to the ground. A gate (denoted by [G] in FIG. 12) of the MOS transistor 51 is connected to the signal generation circuit 52.

That is, the VCSELs 21 and the MOS transistor 51 of the drive unit 50 are connected in series between the power supply line and the ground. The signal generation circuit 52 generates a signal having a “H level” for shifting the MOS transistor 51 to an ON state and a signal having an “L level” for shifting the MOS transistor 51 to an OFF state.

One terminal of each of the capacitors 60 is connected to the power supply line, and the other terminal thereof is connected to the ground.

Next, a method of driving the light source board 20 by low-side driving will be described.

First, it is assumed that a signal generated by the signal generation circuit 52 of the drive unit 50 has an “L level”. In this case, the MOS transistor 51 is in the OFF state. That is, no current flows between the source [S] and the drain [D] of the MOS transistor 51. Thus, no current also flows to the VCSELs 21 connected in series with the MOS transistor 51. That is, the VCSELs 21 do not emit light.

In this case, since the capacitors 60 are connected to a power supply, one terminal of each of the capacitors 60 connected to the power supply line has a power supply potential and the other terminal thereof connected to the ground has a ground potential. Therefore, current flows (charges are supplied) to the capacitors 60 from the power supply, so that the capacitors 60 are charged.

Then, in a case where the signal generated by the signal generation circuit 52 of the drive unit 50 becomes an “H level”, the MOS transistor 51 is shifted from the OFF state to the ON state. After that, a closed loop is configured between the capacitors 60 and the VCSELs 21 and the MOS transistor 51 connected in series, and charges accumulated in the capacitors 60 are supplied to the VCSELs 21 and the MOS transistor 51 connected in series. That is, current flows to the VCSELs 21, so that the VCSELs 21 emit light.

This closed loop is a path (which may be referred to as a current path) through which current for causing the light source board 20 to emit light flows. Since the current for causing the light source board 20 to emit light flows to each capacitor 60, a current path is configured for each capacitor 60. Making the current, which causes the light source board 20 to emit light, flow may be referred to as driving the light source board 20.

In a case where the signal generated by the signal generation circuit 52 of the drive unit 50 becomes an “L level” again, the MOS transistor 51 is shifted from the ON state to the OFF state. Accordingly, the closed loop (current path) between the capacitors 60 and the VCSELs 21 and the MOS transistor 51 connected in series is changed into an open loop, so that current does not flow to the VCSELs 21. Therefore, the VCSELs 21 stop emitting light. Then, current flows (charges are supplied) to the capacitors 60 from the power supply, so that the capacitors 60 are charged.

As described above, each time the signal output from the signal generation circuit 52 is shifted between an “H level” and an “L level”, the MOS transistor 51 is repeatedly turned on and off and the VCSELs 21 repeat light emission and non-light emission. The repetition of turning on and off of the MOS transistor 51 may be referred to as switching.

As described above, in a case where the MOS transistor 51 is shifted from the OFF state to the ON state, charges accumulated in the capacitors 60 are discharged at once and current for light emission is supplied to the VCSELs 21. As a result, the VCSELs 21 are caused to emit light with a short rise time.

### Action of Light Emitting Device 11

In the light emitting device 11 of the present exemplary embodiment, the anode via conductors and the cathode via conductors are densely arranged in rows in the heat dissipation substrate 30 and the circuit board 40 and both the rows face each other with the shortest distance. Accordingly, magnetic lines of force hardly enter between the anode via conductors and between the cathode via conductors, and the via conductors work as a pair of transmission lines of parallel flat plates. Therefore, current flows differentially through the anode via conductors and the cathode via conductors. That is, in the technique of the present disclosure, “the anode via conductors and the cathode via conductors are arranged to face each other” means that a state in which current flows differentially through the anode via conductors and the cathode via conductors is made. In a case where current does not flow differentially since the anode via conductors and the cathode via conductors face each other without being densely arranged or face each other at a distance, it cannot be said that the via conductors face each other.

As a result, current flowing through the heat dissipation substrate 30 and the circuit board 40 maintains transverse electro-magnetic (TEM) waves, and a high-frequency loss is also reduced.

In a plan view, rows of the cathode via conductors are provided on both sides of the central position C of the light source board 20 on which the VCSELs 21 are mounted, and rows of the anode via conductors are provided to face the rows of the cathode via conductors, respectively. However, since the inside of the wire can be considered to be equipotential at a frequency (including harmonics) of a driving signal for the VCSELs 21, it is ensured that current flows evenly through both the rows of the cathode via conductors and the rows of the anode via conductors. As a result, impedance is ideally reduced through parallelization.

Generally, arranging the via conductors in a staggered pattern or alternately arranging the via conductors in a row is also effective in increasing mutual inductance and reducing effective inductance. However, in the former aspect, wiring connection between the anodes and wiring connection between the cathodes cannot be made on a surface layer. Further, in the latter aspect, a space should be provided for mounting between all the anode wires and all the cathode wires of the surface layer, and the pitch of the alternate arrangement cannot be made small.

Accordingly, due to restrictions on mounting the light emitting device 11, it is preferable to adopt a structure in which, for example, the via conductors face each other as in the present exemplary embodiment.

### Modification Example

Although the measurement apparatus 1 of one exemplary embodiment of the present disclosure has been described above, the technique of the present disclosure is not limited to the above-described exemplary embodiment and can also be appropriately changed.

For example, an aspect in which the light emitting device 11 is not provided with the heat dissipation substrate 30 may be adopted.

Further, the circuit board 40 of the light emitting device 11 is not limited to the six-layer board, and may be a multilayer board consisting of a plurality of layers other than six layers.

### Supplementary Note

Regarding the exemplary embodiment described above, the following supplementary notes are further disclosed.
(((1)))

A light emitting device comprising:
a light source board that includes a light emitting element including an anode and a cathode;
a circuit board including a plurality of anode via conductors that conduct from a surface of the circuit board corresponding to a first direction up to a surface of the circuit board corresponding to a second direction opposite to the first direction, are connected to the anode, and are arranged in rows to form anode rows, and a plurality of cathode via conductors that conduct from the surface corresponding to the first direction up to the surface corresponding to the second direction, are connected to the cathode, are provided in the same number as the number of the anode via conductors, and are arranged in rows to form cathode rows, the circuit board holding the light source board on the surface corresponding to the first direction; and
a drive unit that is connected to any one of the anode or the cathode and drives the light source board by switching between an ON state and an OFF state of current for causing the light emitting element to emit light,
wherein the anode rows of the plurality of anode via conductors included in the circuit board and the cathode rows of the plurality of cathode via conductors included in the circuit board are disposed to face each other.
(((2)))

The light emitting device according to (((1))), further comprising:
a capacitor that is connected to the other of the anode or the cathode and supplies the current for causing the light emitting element to emit light,
wherein the drive unit and the capacitor are held on the surface of the circuit board corresponding to the second direction.
(((3)))

The light emitting device according to (((1))) or (((2))),
wherein an anode wire connected to the anode is formed on a surface of the light source board corresponding to the first direction and a cathode wire connected to the cathode is formed on a surface of the light source board corresponding to the second direction, and
the cathode rows are disposed in the circuit board on both sides of a central position of the light source board and the anode rows are disposed in the circuit board on both outer sides of the cathode rows with the central position of the light source board interposed therebetween, in a plan view.
(((4)))

The light emitting device according to (((3))),
wherein the circuit board has a wire for connection to the drive unit, which is formed between extension lines of the two cathode rows disposed on both sides of the central position of the light source board in a plan view from the second direction side.
(((5)))

The light emitting device according to (((3))) or (((4))),
wherein, on the surface of the circuit board corresponding to the second direction, a pair of anode wires each of which connects the anode via conductors of each anode row is formed for the anode rows, respectively, and a pair of ground wires is formed on both outer sides of the pair of anode wires, and
the pair of anode wires and the pair of ground wires are connected to each other by a pair of capacitors that supplies current for causing the light emitting element to emit light.
(((6)))

The light emitting device according to any one of (((1))) to (((5))),
wherein the circuit board is a multilayer board that includes a wiring layer provided on the surface corresponding to the first direction, a wiring layer provided on the surface corresponding to the second direction, and a ground layer for a current path disposed between the wiring layer provided on the surface corresponding to the first direction and the wiring layer provided on the surface corresponding to the second direction, and
each of the plurality of anode via conductors and the plurality of cathode via conductors penetrate through-portions individually provided in the ground layer for a current path.
(((7)))

The light emitting device according to any one of (((1))) to (((6))),
wherein the circuit board is a multilayer board that includes a wiring layer provided on the surface corresponding to the first direction, a wiring layer provided on the surface corresponding to the second direction, a ground layer for a current path disposed between the wiring layer provided on the surface corresponding to the first direction and the wiring layer provided on the surface corresponding to the second direction, and a ground layer for heat dissipation disposed between the wiring layer provided on the surface corresponding to the first direction and the ground layer for a current path, and
the ground layer for heat dissipation is connected to the surface of the light source board corresponding to the second direction via the anode via conductors and the cathode via conductors disposed in the circuit board.
(((8)))

The light emitting device according to (((7))),
wherein the ground layer for heat dissipation is not connected to the ground layer for a current path in a region overlapping with the light source board in a plan view.
(((9)))

The light emitting device according to any one of (((1))) to (((8))), further comprising:
a heat dissipation substrate including a plurality of anode via conductors that conduct from a surface of the heat dissipation substrate corresponding to the first direction up to a surface of the heat dissipation substrate corresponding to the second direction, are connected to the anode of the light emitting element, and are arranged in rows to form anode rows, and a plurality of cathode via conductors that conduct from the surface corresponding to the first direction up to the surface corresponding to the second direction, are connected to the cathode of the light emitting element, are provided in the same number as the number of the anode via conductors, and are arranged in rows to form cathode rows, the heat dissipation substrate holding the light source board on the surface corresponding to the first direction, being connected to the circuit board on the surface corresponding to the second direction, and having a thermal conductivity higher than a thermal conductivity of the circuit board,
wherein the anode rows of the plurality of anode via conductors included in the heat dissipation substrate and the cathode rows of the plurality of cathode via conductors included in the heat dissipation substrate are disposed to face each other.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a light source board that includes a light emitting element including an anode and a cathode;
a circuit board including a plurality of anode via conductors that conduct from a surface of the circuit board corresponding to a first direction up to a surface of the circuit board corresponding to a second direction opposite to the first direction, are connected to the anode, and are arranged in rows to form anode rows, and a plurality of cathode via conductors that conduct from the surface corresponding to the first direction up to the surface corresponding to the second direction, are connected to the cathode, are provided in the same number as the number of the anode via conductors, and are arranged in rows to form cathode rows, the circuit board holding the light source board on the surface corresponding to the first direction; and
a drive unit that is connected to any one of the anode or the cathode and drives the light source board by switching between an ON state and an OFF state of current for causing the light emitting element to emit light,
wherein the anode rows of the plurality of anode via conductors included in the circuit board and the cathode rows of the plurality of cathode via conductors included in the circuit board are disposed to face each other.

2. The light emitting device according to claim 1, further comprising:
a capacitor that is connected to the other of the anode or the cathode and supplies the current for causing the light emitting element to emit light,
wherein the drive unit and the capacitor are held on the surface of the circuit board corresponding to the second direction.

3. The light emitting device according to claim 1,
wherein an anode wire connected to the anode is formed on a surface of the light source board corresponding to the first direction and a cathode wire connected to the cathode is formed on a surface of the light source board corresponding to the second direction, and
the cathode rows are disposed in the circuit board on both sides of a central position of the light source board and the anode rows are disposed in the circuit board on both outer sides of the cathode rows with the central position of the light source board interposed therebetween, in a plan view.

4. The light emitting device according to claim 3,
wherein the circuit board has a wire for connection to the drive unit, which is formed between extension lines of the two cathode rows disposed on both sides of the central position of the light source board in a plan view from the second direction side.

5. The light emitting device according to claim 3,
wherein, on the surface of the circuit board corresponding to the second direction, a pair of anode wires each of which connects the anode via conductors of each anode row is formed for the anode rows, respectively, and a pair of ground wires is formed on both outer sides of the pair of anode wires, and
the pair of anode wires and the pair of ground wires are connected to each other by a pair of capacitors that supplies current for causing the light emitting element to emit light.

6. The light emitting device according to claim 1,
wherein the circuit board is a multilayer board that includes a wiring layer provided on the surface corresponding to the first direction, a wiring layer provided on the surface corresponding to the second direction, and a ground layer for a current path disposed between the wiring layer provided on the surface corresponding to the first direction and the wiring layer provided on the surface corresponding to the second direction, and
each of the plurality of anode via conductors and the plurality of cathode via conductors penetrate through-portions individually provided in the ground layer for a current path.

7. The light emitting device according to claim 1,
wherein the circuit board is a multilayer board that includes a wiring layer provided on the surface corresponding to the first direction, a wiring layer provided on the surface corresponding to the second direction, a ground layer for a current path disposed between the wiring layer provided on the surface corresponding to the first direction and the wiring layer provided on the surface corresponding to the second direction, and a ground layer for heat dissipation disposed between the wiring layer provided on the surface corresponding to the first direction and the ground layer for a current path, and
the ground layer for heat dissipation is connected to the surface of the light source board corresponding to the second direction via the anode via conductors and the cathode via conductors disposed in the circuit board.

8. The light emitting device according to claim 7,
wherein the ground layer for heat dissipation is not connected to the ground layer for a current path in a region overlapping with the light source board in a plan view.

9. The light emitting device according to claim 1, further comprising:
a heat dissipation substrate including a plurality of anode via conductors that conduct from a surface of the heat dissipation substrate corresponding to the first direction up to a surface of the heat dissipation substrate corresponding to the second direction, are connected to the anode of the light emitting element, and are arranged in rows to form anode rows, and a plurality of cathode via conductors that conduct from the surface corresponding to the first direction up to the surface corresponding to the second direction, are connected to the cathode of the light emitting element, are provided in the same number as the number of the anode via conductors, and are arranged in rows to form cathode rows, the heat dissipation substrate holding the light source board on the surface corresponding to the first direction, being connected to the circuit board on the surface corresponding to the second direction, and having a thermal conductivity higher than a thermal conductivity of the circuit board,
wherein the anode rows of the plurality of anode via conductors included in the heat dissipation substrate and the cathode rows of the plurality of cathode via conductors included in the heat dissipation substrate are disposed to face each other.
